(19) United States
(12) Patent Application Publication
(10) Pub. No.: US 2025/0239543 A1
(43) Pub. Date: Jul. 24, 2025

(54) SEMICONDUCTOR DEVICE AND SEMICONDUCTOR PACKAGE WITH REDISTRIBUTION LINE

(71) Applicant: SK hynix Inc., Icheon-si Gyeonggi-do (KR)

(72) Inventors: Jae Yong AN, Icheon-si Gyeonggi-do (KR); Yoon Jae LEE, Icheon-si Gyeonggi-do (KR)

(73) Assignee: SK hynix Inc., Icheon-si Gyeonggi-do (KR)

(21) Appl. No.: 18/790,439

(22) Filed: Jul. 31, 2024

(30) Foreign Application Priority Data
Jan. 18, 2024 (KR) 10-2024-0008174

(51) Int. Cl. H01L 23/00; H01L 25/065

(52) U.S. Cl. CPC H01L 24/02; H01L 24/16; H01L 24/48; H01L 24/73; H01L 25/0657; H01L 24/32; H01L 2224/02331; H01L 2224/0235; H01L 2224/02373; H01L 2224/0239; H01L 2224/16147; H01L 2224/32225; H01L 2224/48227; H01L 2224/73207; H01L 2224/73253; H01L 2224/73265; H01L 2225/0651; H01L 2225/06513; H01L 2225/06562; H01L 2924/182

(57) ABSTRACT

A semiconductor device includes a semiconductor chip having a chip pad; a redistribution line disposed on the semiconductor chip; and a first dielectric layer disposed on the semiconductor chip and the redistribution line. The redistribution line is connected to the chip pad and has a wire bonding pad section. The first dielectric layer has a first opening that exposes the wire bonding pad section. The redistribution line includes a copper layer, a nickel layer on the copper layer, and a gold layer on the nickel layer. The nickel layer comprises a side surface protruding beyond a side surface of the copper layer.

### CROSS-REFERENCE TO RELATED APPLICATION

The present application claims priority under 35 U.S.C. § 119 (a) to Korean Patent Application No. 10-2024-0008174 filed in the Korean Intellectual Property Office on Jan. 18, 2024, which application is incorporated herein by reference in its entirety.

### BACKGROUND

### 1. Technical Field

Various embodiments of the disclosed technology generally relate to a semiconductor device and a semiconductor package with a redistribution line.

### 2. Related Art

A semiconductor device includes an integrated circuit for storing or processing data, and has a chip pad for inputting data to the integrated circuit or outputting data of the integrated circuit to the outside.

The semiconductor device may include a redistribution line (RDL) pattern. The redistribution line may be electrically connected to the chip pad, and may extend from a region where the chip pad is disposed to another region. The redistribution line may substantially extend the chip pad to a connection point with an electrical connection member such as a wire and/or a bump. By the redistribution line, the electrical connection point where the connection member is connected to the semiconductor device may be changed to a location that is separated from the location of the chip pad.

### SUMMARY

In an embodiment, a semiconductor device may include: a semiconductor chip having a chip pad; a redistribution line disposed on the semiconductor chip; and a first dielectric layer disposed on the semiconductor chip and the redistribution line. The redistribution line is connected to the chip pad, and has a wire bonding pad section. The first dielectric layer has a first opening that exposes the wire bonding pad section. The redistribution line includes a copper layer, a nickel layer on the copper layer, and a gold layer on the nickel layer. The nickel layer has a side surface protruding beyond a side surface of the copper layer.

In an embodiment, a semiconductor device may include: a semiconductor chip; a redistribution line disposed on the semiconductor chip; and a first dielectric layer disposed on the semiconductor chip and the redistribution line. The redistribution line has a wire bonding pad section. The first dielectric layer has a first opening that exposes the wire bonding pad section. The redistribution line includes an electrically conductive layer, a barrier metal layer on the electrically conductive layer, and a bonding metal layer on the barrier metal layer. The barrier metal layer has a flange section protruding beyond a side surface of the electrically conductive layer.

In an embodiment, a semiconductor package may include: a first semiconductor device including a first semiconductor chip, a redistribution line disposed on the first semiconductor chip, and a first dielectric layer disposed on the first semiconductor chip and the redistribution line; and a second semiconductor device stacked on the first semiconductor device. The redistribution line has a wire bonding pad section and a bump bonding pad section. The first dielectric layer has a first opening that exposes the wire bonding pad section, and a second opening that exposes the bump bonding pad section. The second semiconductor device includes a second semiconductor chip and a conductive bump connected to the second semiconductor chip. The conductive bump is bonded to the bump bonding pad section of the redistribution line. The redistribution line includes an electrically conductive layer, a barrier metal layer on the electrically conductive layer, and a bonding metal layer on the barrier metal layer. The barrier metal layer has a side surface protruding beyond a side surface of the electrically conductive layer.

### BRIEF DESCRIPTION OF THE DRAWINGS

FIG. 1 is a schematic plan view of a semiconductor device based on an embodiment of the disclosed technology.

FIG. 2 is a cross-sectional view of an embodiment taken along a line A-A′ of FIG. 1.

FIG. 3 is an enlarged plan view illustrating a redistribution line and a first dielectric layer of the semiconductor device based on an embodiment of the disclosed technology.

FIG. 4 is a cross-sectional view of an embodiment taken along a line B-B′ of FIG. 3.

FIG. 5 is a cross-sectional view of an embodiment taken along a line C-C′ of FIG. 3.

FIG. 6 is a cross-sectional view of an embodiment taken along a line D-D′ of FIG. 3.

FIG. 7 is a cross-sectional view of an embodiment taken along a line E-E′ of FIG. 3.

FIGS. 8, 9, 10, 11, 12, and 13 are views illustrating a method for forming a semiconductor device based on an embodiment of the disclosed technology.

FIG. 14 is a cross-sectional view of a semiconductor package based on an embodiment of the disclosed technology.

### DETAILED DESCRIPTION

Hereinafter, embodiments of the disclosed technology will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled” or “linked” with each other. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. Spatially relative terms, such as “under,” “on,” “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings.

Various embodiments of the disclosed technology are directed to providing a semiconductor device and a semiconductor package with a redistribution line.

According to various embodiments of the disclosed technology, it is possible to provide a semiconductor device and a semiconductor package with a redistribution line having a wire bonding pad.

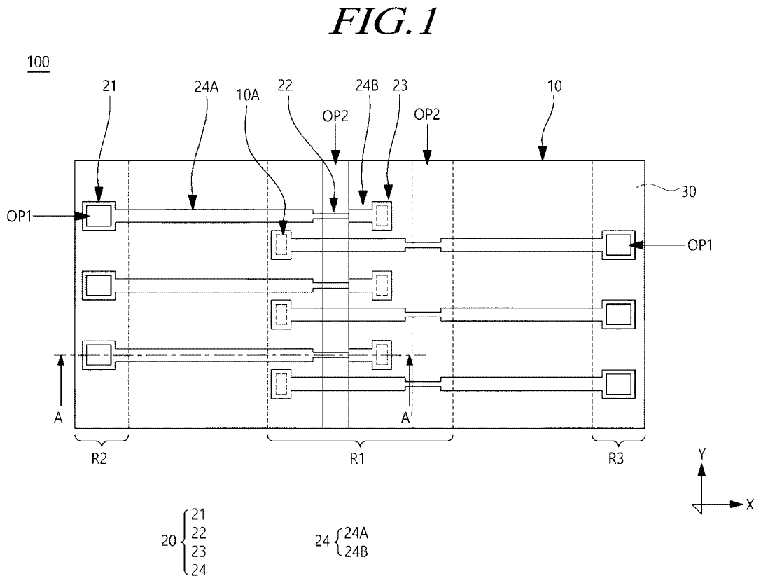

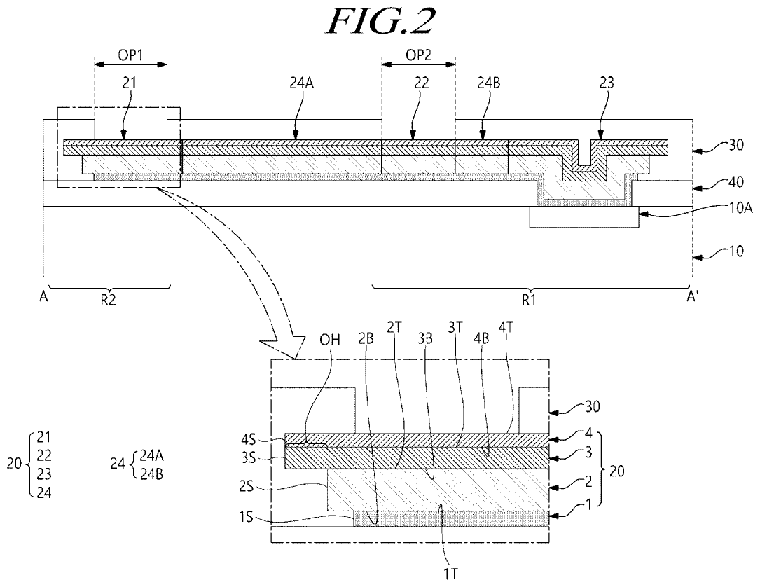

FIG. 1 is a schematic plan view of a semiconductor device based on an embodiment of the disclosed technology, and FIG. 2 is a cross-sectional view of an embodiment taken along a line A-A′ of FIG. 1.

Referring to FIGS. 1 and 2, the semiconductor device 100 based on the embodiment of the disclosed technology may include a semiconductor chip 10, a plurality of redistribution lines 20, and a first dielectric layer 30.

An integrated circuit (not illustrated) including cell transistors may be integrated into the semiconductor chip 10. The semiconductor chip 10 has a plurality of chip pads 10A. The chip pads 10A may be electrically connected to the integrated circuit through interconnection patterns (not illustrated) inside the semiconductor chip 10. The chip pads 10A are provided as connection terminals which electrically connect the semiconductor chip 10 to an external device.

The chip pads 10A may be disposed in a first region R1 of the semiconductor chip 10. The first region R1 may be the center region of the semiconductor chip 10 in the X-axis direction of an X-Y plane. The semiconductor chip 10 may be a center pad type semiconductor chip. The chip pads 10A may be disposed in two columns in the Y-axis direction of the X-Y plane in the first region R1 of the semiconductor chip 10. However, the disclosed technology is not limited thereto, and the arrangement of the chip pads 10A may be changed in various ways. A second region R2 and a third region R3 in FIG. 1 as both edge regions of the semiconductor chip 10 in the X-axis direction may be spaced apart from the first region R1 in the X-axis direction.

The semiconductor chip 10 may include a nonvolatile memory such as a NAND flash memory, a NOR flash memory, a PRAM (phase change random access memory) and an MRAM (magneto-resistive random access memory), a volatile memory such as a DRAM (dynamic random access memory) and an SRAM (static random access memory), or a processor such as a CPU (central processing unit), a GPU (graphics processing unit), an AP (application processor) and an NPU (neural processing unit), etc.

The redistribution lines 20 may be disposed on the semiconductor chip 10. The redistribution lines 20 may extend from the first region R1 to the second region R2 or the third region R3 of the semiconductor chip 10. As illustrated in FIG. 1, among six redistribution lines 20, three redistribution lines 20 may extend from the first region R1 to the second region R2, and the remaining three redistribution lines may extend from the first region R1 to the third region R3.

Each redistribution line 20 may include a wire bonding pad section 21, a bump bonding pad section 22, an overlapping pad section 23, and trace sections 24: 24A and 24B connecting them to each other.

The wire bonding pad sections 21 of the redistribution lines may be disposed on the second region R2 and the third region R3 of the semiconductor chip 10. For example, as in FIG. 1, the wire bonding pad sections 21 of the three redistribution lines 20 among the six redistribution lines 20 may be disposed on the second region R2, and the wire bonding pad sections 21 of the remaining three redistribution lines 20 may be disposed on the third region R3. The overlapping pad sections 23 of the redistribution lines 20 may be disposed on the first region R1 of the semiconductor chip 10. The bump bonding pad sections 22 of the redistribution lines 20 may be disposed to be spaced apart from the overlapping pad sections 23 on the first region R1 of the semiconductor chip 10.

The overlapping pad sections 23 of the redistribution lines may overlap the chip pads 10A of the semiconductor chip 10. The overlapping pad section 23 is electrically connected to the chip pad 10A, and the trace sections 24A: 24A and 24B, the wire bonding pad section 21 and the bump bonding pad section 22 are connected to the overlapping pad section 23. The redistribution line 20 may extend from the chip pad 10A which is disposed in the first region R1 of the semiconductor chip 10 to the second region R2 or the third region R3 where the wire bonding pad section 21 is disposed.

The overlapping pad sections 23 of the redistribution lines may be disposed in two columns in the Y-axis direction on the first region R1 of the semiconductor chip 10. However, the disclosed technology is not limited thereto, and the arrangement of the overlapping pad sections 23 may vary depending on the arrangement of the chip pads 10A.

The wire bonding pad sections 21 of the redistribution lines may be disposed in the Y-axis direction on the second region R2 and the third region R3 of the semiconductor chip 10. As illustrated in FIG. 1, the wire bonding pad sections 21 of the three redistribution lines 20 among the six redistribution lines 20 may be disposed in one column in the Y-axis direction on the second region R2, and the wire bonding pad sections 21 of the remaining three redistribution lines 20 may be disposed in one column in the Y-axis direction on the third region R3. As illustrated in FIG. 1, the bump bonding pad sections 22 of the redistribution lines 20 may be disposed in two columns in the Y-axis direction on the first region R1 of the semiconductor chip 10. The bump bonding pad sections 22 of the redistribution lines 20 may be disposed by being offset in the X-axis direction with respect to the chip pads 10A of the semiconductor chip 10.

The trace sections 24: 24A and 24B of the redistribution line 20 may include a first trace section 24A and a second trace section 24B. The first trace section 24A may connect the wire bonding pad section 21 and the bump bonding pad section 22, and the second trace section 24B may connect the bump bonding pad section 22 and the overlapping pad section 23.

The wire bonding pad section 21 is connected to one end of the first trace section 24A, and may have a larger width than the first trace section 24A.

The bump bonding pad section 22 may be connected between the other end of the first trace section 24A which is opposite to the one end of the first trace section 24A and one end of the second trace section 24B. In FIG. 1, the first and second trace sections 24A and 24B have a constant width and the bump bonding pad section 22 has a smaller width compared to the first and second trace sections 24A and 24B, but the embodiment of the disclosed technology is not limited thereto. The width of the first and second trace sections 24A and 24B might not be constant, and the width of the bump bonding pad section 22 may have a size that is smaller than a maximum width and larger than a minimum width of the first and second trace sections 24A and 24B.

The overlapping pad section 23 may be connected to the other end of the second trace section 24B which is opposite to the one end of the second trace section 24B, and may have a larger width compared to the second trace section 24B.

A second dielectric layer 40 having openings which expose the chip pads 10A may be disposed on the semiconductor chip 10. The second dielectric layer 40 may cover the top surface of the semiconductor chip 10, and may expose the chip pads 10A. The second dielectric layer 40 may electrically isolate the redistribution lines 20 from the semiconductor chip 10. The second dielectric layer 40 may include a photosensitive polymer material such as polyimide.

The redistribution line 20 may be disposed on the second dielectric layer 40 and the chip pad 10A which is exposed by the opening of the second dielectric layer 40. The redistribution line 20 may be configured to include an electrically conductive layer 2, a barrier metal layer 3 on the electrically conductive layer 2, and a bonding metal layer 4 on the barrier metal layer 3. Besides, the redistribution line 20 may further include a base metal layer 1 under the electrically conductive layer 2.

The base metal layer 1 may be disposed on the surface of the second dielectric layer 40 and the surface of the chip pad 10A. The base metal layer 1 may be disposed between the electrically conductive layer 2 and the second dielectric layer 40. The base metal layer 1 may be extended to be disposed between the electrically conductive layer 2 and the chip pad 10A. The base metal layer 1 may contact the chip pad 10A of the semiconductor chip 10, and may electrically connect the chip pad 10A and the electrically conductive layer 2.

The base metal layer 1 may adhere to the second dielectric layer 40, the chip pad 10A and the electrically conductive layer 2. The base metal layer 1 may suppress a metal included in the electrically conductive layer 2 from diffusing to the semiconductor chip 10. The base metal layer 1 may provide the base of the redistribution line 20. The base metal layer 1 may include titanium (Ti) or titanium tungsten (TiW). The base metal layer 1 may be a titanium layer.

The electrically conductive layer 2 may be disposed on a top surface 1T of the base metal layer 1. The electrically conductive layer 2 includes a bottom surface 2B which faces the top surface 1T of the base metal layer 1, a top surface 2T which is opposite to the bottom surface 2B, and a side surface 2S which connects the edge of the bottom surface 2B and the edge of the top surface 2T. The outer peripheral section of the electrically conductive layer 2 has an overhang structure which is not supported by the underlying base metal layer 1. The outer peripheral section of the electrically conductive layer 2 has the overhang structure which is continuous along a side surface 1S of the base metal layer 1. The side surface 2S of the electrically conductive layer 2 may protrude beyond the side surface 1S of the base metal layer 1. The electrically conductive layer 2 may include copper (Cu). The electrically conductive layer 2 may be a copper layer.

The barrier metal layer 3 is disposed on the top surface 2T of the electrically conductive layer 2. The barrier metal layer 3 includes a bottom surface 3B which faces the top surface 2T of the electrically conductive layer 2, a top surface 3T which is opposite to the bottom surface 3B, and a side surface 3S which connects the edge of the bottom surface 3B and the edge of the top surface 3T.

As will be described later, the bonding metal layer 4 may include gold. When bonding a solder to the bump bonding pad section 22, the gold of the bonding metal layer 4 may disappear by diffusing to the solder. In an embodiment, the copper of the electrically conductive layer 2 may diffuse to an interface with the solder, and accordingly, an intermetallic compound may be generated. The barrier metal layer 3 may suppress the copper of the electrically conductive layer 2 from diffusing to the interface with the solder to reduce the consumption of the copper of the electrically conductive layer 2 and prevent or mitigate a thick intermetallic compound from being generated. The barrier metal layer 3 may be made of a metal material which adheres to the copper of the electrically conductive layer 2 and the gold (Au) of the bonding metal layer 4. The barrier metal layer 3 may include nickel (Ni). The barrier metal layer 3 may be a nickel layer.

The barrier metal layer 3 has a flange section OH which protrudes beyond the side surface 2S of the electrically conductive layer 2. The flange section OH of the barrier metal layer 3 has an overhang structure which is not supported by the underlying electrically conductive layer 2. The flange section OH of the barrier metal layer 3 has the overhang structure which is continuous along the side surface 2S of the electrically conductive layer 2. The side surface 3S of the barrier metal layer 3 may protrude beyond the side surface 2S of the electrically conductive layer 2.

The bonding metal layer 4 is disposed on the top surface 3T of the barrier metal layer 3. The bonding metal layer 4 includes a bottom surface 4B which faces the top surface 3T of the barrier metal layer 3, a top surface 4T which is opposite to the bottom surface 4B, and a side surface 4S which connects the edge of the bottom surface 4B and the edge of the top surface 4T. As illustrated in FIG. 2, the side surface 4S of the bonding metal layer 4 may be aligned with the side surface 3S of the barrier metal layer 3, but the embodiment of the disclosed technology is not limited thereto.

The bonding metal layer 4 may include a metal capable of wire bonding. The bonding metal layer 4 may include gold (Au). The bonding metal layer 4 may be a gold layer.

The first dielectric layer 30 may be disposed on the second dielectric layer 40 and the redistribution lines 20. The first dielectric layer 30 may be extended on a top surface of the bonding metal layer 4 to expose the wire bonding pad section 23. The first dielectric layer may protect the redistribution lines 20. The first dielectric layer 30 may include a photosensitive polymer material such as polyimide.

The first dielectric layer 30 covers the overlapping pad sections 23 and the trace sections 24 of the redistribution lines 20, and has openings OP1 and OP2 which expose the wire bonding pad sections 21 and the bump bonding pad sections 22 of the redistribution lines 20. The openings OP1 and OP2 include first openings OP1 which expose the wire bonding pad sections 21 and second openings OP2 which expose the bump bonding pad sections 22.

The first openings OP1 are provided to individually expose the wire bonding pad sections 21 of the redistribution lines 20. The first openings OP1 correspond one-to-one to the wire bonding pad sections 21, and each may expose a corresponding wire bonding pad section 21. Although not illustrated, a metal wire may be bonded to the surface of the wire bonding pad section 21 which is exposed by the first opening OP1 of the first dielectric layer 30. The metal wire may be connected to the wire bonding pad section 21, and may be electrically connected to the chip pad 10A via the first and second trace sections 24A and 24B and the bump bonding pad section 22.

As illustrated in FIG. 1, the second openings OP2 may be configured in the form of a line extending in the Y-axis direction to simultaneously expose the bump bonding pad sections 22 which are disposed in a line in the Y-axis direction. In correspondence to the arrangement structure of the bump bonding pad sections 22 which are disposed in two columns in the Y-axis direction, the second openings OP2 of two columns which are in the form of lines extending in the Y-axis direction may be configured in the first dielectric layer 30. A conductive bump may be bonded to the surface of the bump bonding pad section 22 which is exposed by the second opening OP2 of the first dielectric layer 30. The conductive bump may be connected to the bump bonding pad section 22, and may be electrically connected to the chip pad 10A via the second trace section 24B.

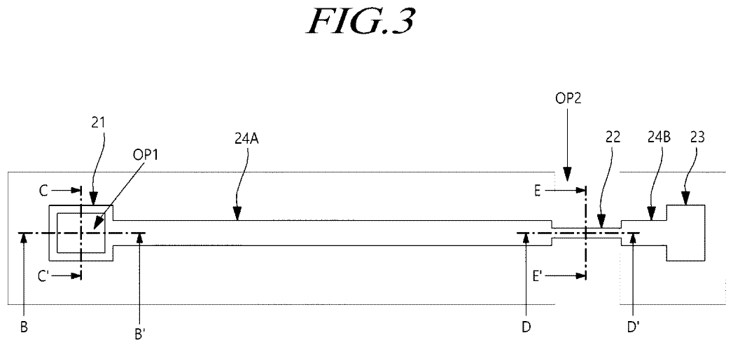

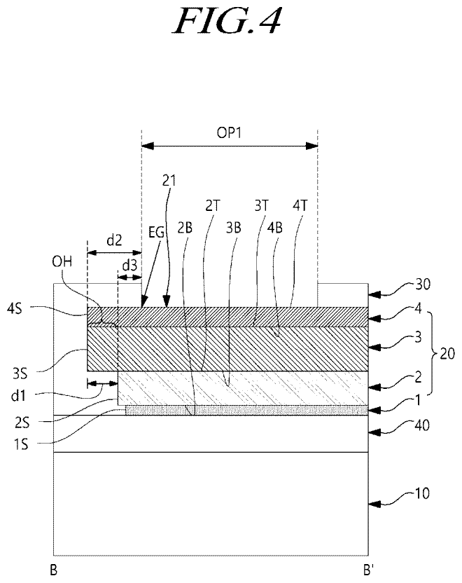

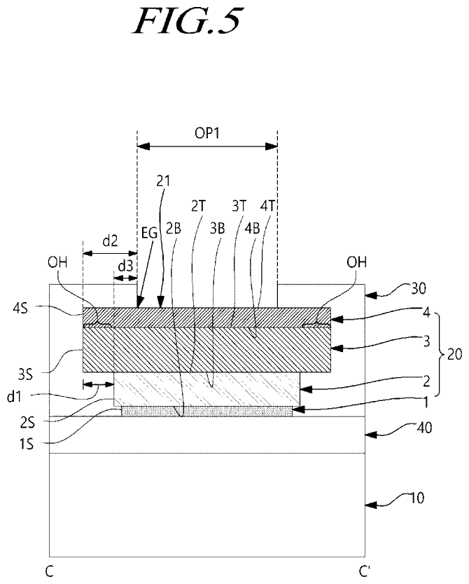

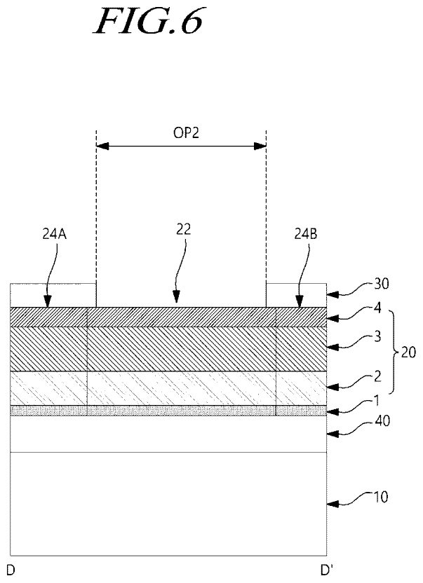

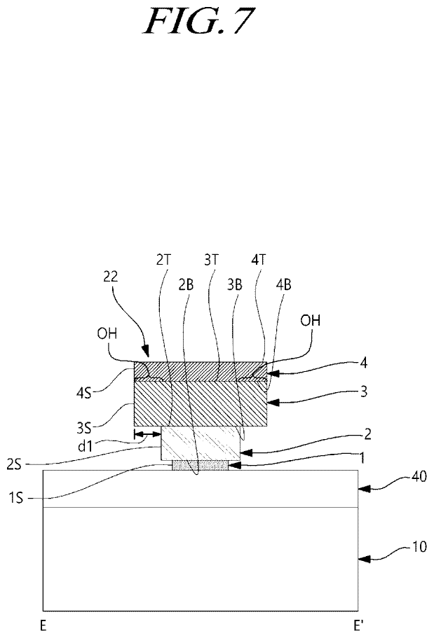

FIG. 3 is an enlarged plan view illustrating the redistribution line and the first dielectric layer of the semiconductor device based on the embodiment of the disclosed technology, FIG. 4 is a cross-sectional view taken along a line B-B′ of FIG. 3, FIG. 5 is a cross-sectional view taken along a line C-C′ of FIG. 3, FIG. 6 is a cross-sectional view taken along a line D-D′ of FIG. 3, and FIG. 7 is a cross-sectional view taken along a line E-E′ of FIG. 3.

Referring to FIGS. 3 to 5, in the wire bonding pad section 21, the flange section OH of the barrier metal layer 3 protrudes beyond the side surface 2S of the electrically conductive layer 2. In the wire bonding pad section 21, the flange section OH of the barrier metal layer 3 has the overhang structure which is not supported by the underlying electrically conductive layer 2. The width of the flange section OH of the barrier metal layer 3 of the wire bonding pad section 21 may be d1. In the wire bonding pad section 21, the flange section OH of the barrier metal layer 3 has the overhang structure which is continuous along the side surface 2S of the electrically conductive layer 2.

In the wire bonding pad section 21, the side surface 3S of the barrier metal layer 3 may protrude beyond the side surface 2S of the underlying electrically conductive layer 2. In the wire bonding pad section 21, the side surface 3S of the barrier metal layer 3 may be spaced apart from the side surface 2S of the underlying electrically conductive layer 2 by a distance of d1. In the wire bonding pad section 21, the edge section of the bottom surface 3B of the barrier metal layer 3 which connects the side surface 3S of the barrier metal layer 3 and the side surface 2S of the electrically conductive layer 2 does not overlap the electrically conductive layer 2.

In the wire bonding pad section 21, the outer peripheral section of the electrically conductive layer 2 has the overhang structure which is not supported by the underlying base metal layer 1. In the wire bonding pad section 21, the outer peripheral section of the electrically conductive layer 2 has the overhang structure which is continuous along the side surface 1S of the base metal layer 1. In the wire bonding pad section 21, the side surface 2S of the electrically conductive layer 2 may protrude beyond the side surface 1S of the base metal layer 1.

The first dielectric layer 30 is provided to cover the side surface of the wire bonding pad section 21. Specifically, the first dielectric layer 30 is provided to cover, in the wire bonding pad section 21, the side surface 4S of the bonding metal layer 4, the side surface 3S of the barrier metal layer 3, the side surface 2S of the electrically conductive layer 2 and the side surface 1S of the base metal layer 1. In addition, the first dielectric layer 30 is provided to cover, in the wire bonding pad section 21, the edge section of the bottom surface 3B of the barrier metal layer 3 between the side surface 2S of the electrically conductive layer 2 and the side surface 3S of the barrier metal layer 3.

In the wire bonding pad section 21, in an embodiment, the first dielectric layer 30 may cover the side surface 3S of the barrier metal layer 3 to prevent or mitigate a layer acting as a metal diffusion path from being generated. If the side surface 3S of the barrier metal layer 3 is exposed, as process by-products combine with the exposed side surface 3S in a subsequent process, a metal inorganic compound may be formed. When the barrier metal layer 3 includes nickel, the metal inorganic compound may be nickel sulfide in which nickel combines with sulfur. The layer of the metal inorganic compound may provide a path through which the metal of the electrically conductive layer 2 moves. When the electrically conductive layer 2 includes copper, as the copper is ionized, the copper may diffuse to the bonding metal layer 4. In an embodiment, the diffused copper may be oxidized again to cause discoloration of the surface of the bonding metal layer 4 and hinder a metal wire from being bonded to the bonding metal layer 4. In an embodiment, because the first dielectric layer 30 suppresses the generation of the metal diffusion path, it is possible to suppress or prevent the occurrence of a defect in which the surface of the bonding metal layer 4 is discolored or a metal wire comes off without being bonded to the bonding metal layer 4.

The first dielectric layer 30 may extend to cover, in the wire bonding pad section 21, the edge section of the top surface 4T of the bonding metal layer 4. Accordingly, an edge EG of the first opening OP1 may be spaced apart from the side surface 4S of the bonding metal layer 4. As illustrated in FIG. 4, the edge EG of the first opening OP1 may be spaced apart from the side surface 4S of the bonding metal layer 4 by a distance of d2. The edge EG of the first opening OP1 may be disposed on the top surface 4T of the bonding metal layer 4, and the first dielectric layer 30 may continuously cover the edge section of the top surface 4T of the bonding metal layer 4 along the edge EG of the first opening OP1.

A metal wire may be bonded to the exposed section of the top surface 4T of the bonding metal layer 4 of the wire bonding pad section 21 which is exposed by the first opening OP1 of the first dielectric layer 30. The exposed section of the top surface 4T of the bonding metal layer 4 of the wire bonding pad section 21 which is exposed by the first opening OP1 may be defined as a wire bonding area. The wire bonding area may be spaced apart, by a distance of d3, from the flange section OH of the barrier metal layer 3 which has the overhang structure. The distance d3 has a size corresponding to the difference between the distance d2 and the distance d1. The wire bonding area might not overlap the flange section OH of the barrier metal layer 3.

A metal element which forms the electrically conductive layer 2 may be ionized when exposed to moisture. When the electrically conductive layer 2 includes copper, the copper of the electrically conductive layer 2 may be ionized, and then, may diffuse to the wire bonding area along the surfaces of conductive layers which are disposed between the electrically conductive layer 2 and the wire bonding area.

According to an embodiment of the disclosed technology, by extending the first dielectric layer 30 to cover the edge section of the top surface 4T of the bonding metal layer 4 of the wire bonding pad section 21, it is possible to prevent or mitigate external moisture from penetrating into the electrically conductive layer 2, thereby suppressing the copper of the electrically conductive layer 2 from being ionized. According to an embodiment of the disclosed technology, by configuring the side surface 3S of the barrier metal layer 3 in the wire bonding pad section 21 to protrude beyond the side surface 2S of the underlying electrically conductive layer 2, the length of a path, that is, the length of a diffusion path, for the copper of the electrically conductive layer 2 to reach the wire bonding area may be increased. According to this fact, in an embodiment, it is possible to suppress or prevent the copper of the electrically conductive layer 2 from diffusing to the wire bonding area, and it is possible to suppress or prevent a defect such as discoloration of the wire bonding area and the coming-off of a metal wire.

Referring to FIGS. 3, 6 and 7, in the bump bonding pad section 22, the flange section OH of the barrier metal layer 3 protrudes beyond the side surface 2S of the electrically conductive layer 2. In the bump bonding pad section 22, the flange section OH of the barrier metal layer 3 has the overhang structure which is not supported by the underlying electrically conductive layer 2. The flange section OH of the barrier metal layer 3 of the bump bonding pad section 22 has the overhang structure which is continuous along the side surface 2S of the electrically conductive layer 2. The width of the flange section OH of the barrier metal layer 3 of the bump bonding pad section 22 may be d1.

In the bump bonding pad section 22, the side surface 3S of the barrier metal layer 3 protrudes beyond the side surface 2S of the underlying electrically conductive layer 2. The side surface 3S of the barrier metal layer 3 of the bump bonding pad section 22 may be spaced apart from the side surface 2S of the underlying electrically conductive layer 2 by a distance of d1. In the bump bonding pad section 22, the edge section of the bottom surface 3B of the barrier metal layer 3 which connects the side surface 3S of the barrier metal layer 3 and the side surface 2S of the electrically conductive layer 2 does not overlap the electrically conductive layer 2.

In the bump bonding pad section 22, the outer peripheral section of the electrically conductive layer 2 has the overhang structure which is not supported by the base metal layer 1. In the bump bonding pad section 22, the outer peripheral section of the electrically conductive layer 2 has the overhang structure which is continuous along the side surface 1S of the base metal layer 1. In the bump bonding pad section 22, the side surface 2S of the electrically conductive layer 2 protrudes beyond the side surface 1S of the underlying base metal layer 1.

The second opening OP2 of the first dielectric layer 30 is provided to expose the bump bonding pad section 22. The second opening OP2 is provided to expose, in the bump bonding pad section 22, the top surface 4T and the side surface 4S of the bonding metal layer 4, the side surface 3S of the barrier metal layer 3, the side surface 2S of the electrically conductive layer 2, the edge section of the bottom surface 3B of the barrier metal layer 3 between the side surface 3S of the barrier metal layer 3 and the side surface 2S of the electrically conductive layer 2, and the side surface 1S of the base metal layer 1.

The bump bonding pad section 22 may be a structure to be coupled with a bump including a solder layer. In an embodiment, solder coupling is performed at a higher temperature than bonding wire coupling, and an intermetallic compound layer is thickly formed. Therefore, in an embodiment, copper oxide formed on the surface of the bump bonding pad section 22 might not have significant effect on bondability.

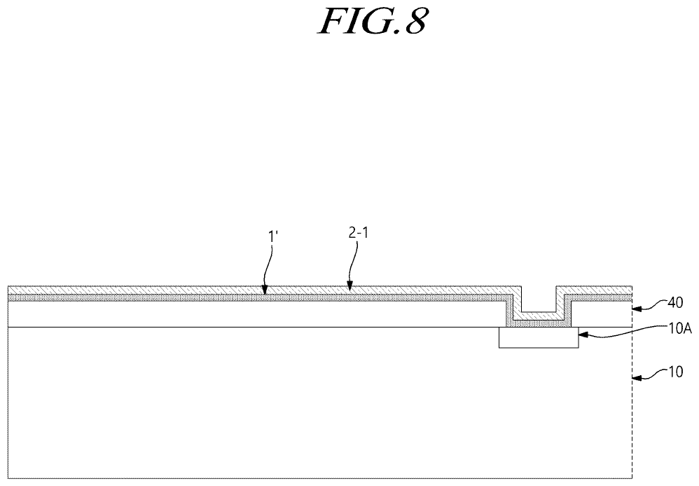

FIGS. 8 to 13 are views illustrating a method for forming a semiconductor device based on an embodiment of the disclosed technology.

Referring to FIG. 8, a pre-base metal layer 1′ may be formed on a semiconductor chip 10, and a seed layer 2-1 may be formed on the pre-base metal layer 1′.

A second dielectric layer 40 having an opening which exposes a chip pad 10A may be further disposed on the semiconductor chip 10. The pre-base metal layer 1′ may be formed on the surface of the second dielectric layer 40 and the surface of the chip pad 10A which is exposed by the opening of the second dielectric layer 40. The seed layer 2-1 may be formed on the surface of the pre-base metal layer 1′.

The pre-base metal layer 1′ and the seed layer 2-1 may be formed by a deposition method such as sputtering. The pre-base metal layer 1′ may include titanium or titanium tungsten, and the seed layer 2-1 may include copper.

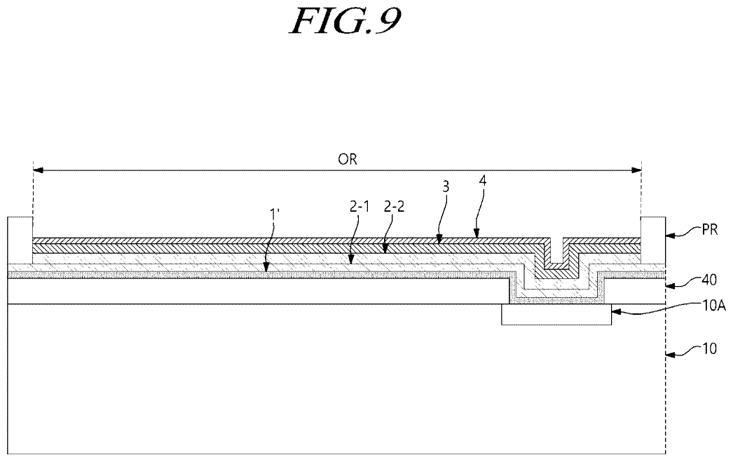

Referring to FIG. 9, a plating resist pattern PR may be formed on the seed layer 2-1. The plating resist pattern PR may be patterned to have an opening region OR which provides a template for the redistribution line 20 of FIG. 2. The plating resist pattern PR may be patterned by forming a resist layer and selectively exposing and developing the resist layer.

In the opening region OR of the plating resist pattern PR, a conductive layer 2-2, a barrier metal layer 3 and a bonding metal layer 4 may be sequentially grown.

The conductive layer 2-2 may be grown on the seed layer 2-1 through a plating process. The barrier metal layer 3 may be grown on the conductive layer 2-2 through a plating process. The bonding metal layer 4 may be grown on the barrier metal layer 3 through a plating process. The conductive layer 2-2 may include copper, the barrier metal layer 3 may include nickel, and the bonding metal layer 4 may include gold.

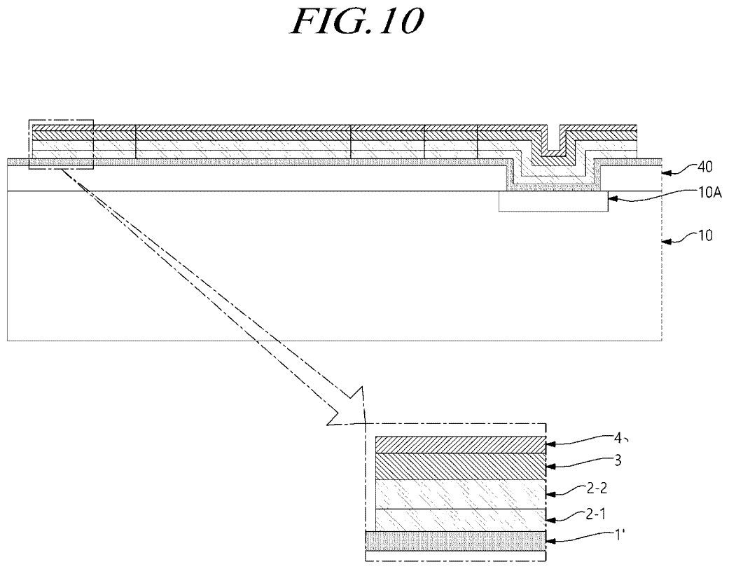

Referring to FIG. 10, the plating resist pattern PR (see FIG. 9) may be removed through a strip process. In the strip process, a stripper including a sulfur(S) constituent may be used.

A section of the seed layer 2-1 which does not overlap the conductive layer 2-2 may be removed. In other words, a section of the seed layer 2-1 (see FIG. 9) which is exposed due to the removal of the plating resist pattern PR (see FIG. 9) may be selectively etched and removed.

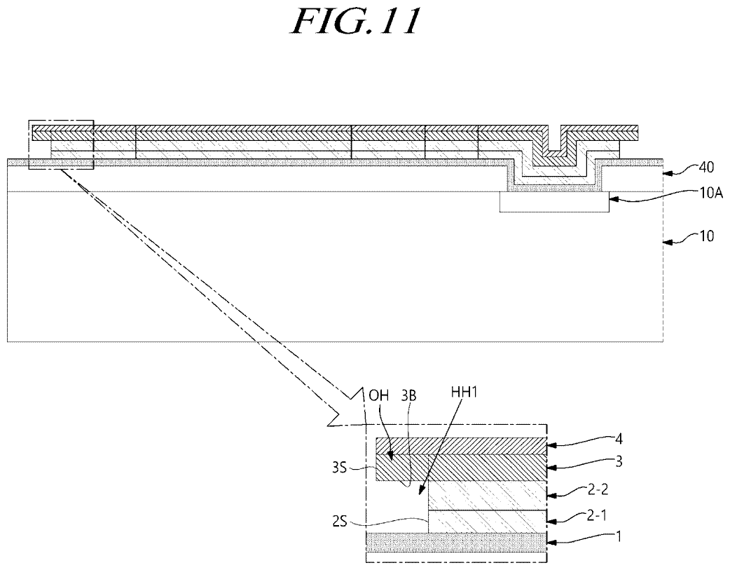

Referring to FIG. 11, the side surface of the seed layer 2-1 and the side surface of the conductive layer 2-2 may be recessed through an etching process. The seed layer 2-1 and the conductive layer 2-2 which remain after the etching process may configure an electrically conductive layer 2.

An isotropic etching process may be used as the etching process. As a result of the etching process, a first horizontal groove HH1 may be formed under a flange section OH of the barrier metal layer 3. The first horizontal groove HH1 extends continuously along a side surface 2S of the electrically conductive layer 2.

As the first horizontal groove HH1 is formed, the flange section OH of the barrier metal layer 3 may have an overhang structure which is not supported by the electrically conductive layer 2. A side surface 3S of the barrier metal layer 3 may be spaced apart from the side surface 2S of the electrically conductive layer 2, and the edge section of a bottom surface 3B of the barrier metal layer 3 may be exposed between the side surface 3S of the barrier metal layer 3 and the side surface 2S of the electrically conductive layer 2.

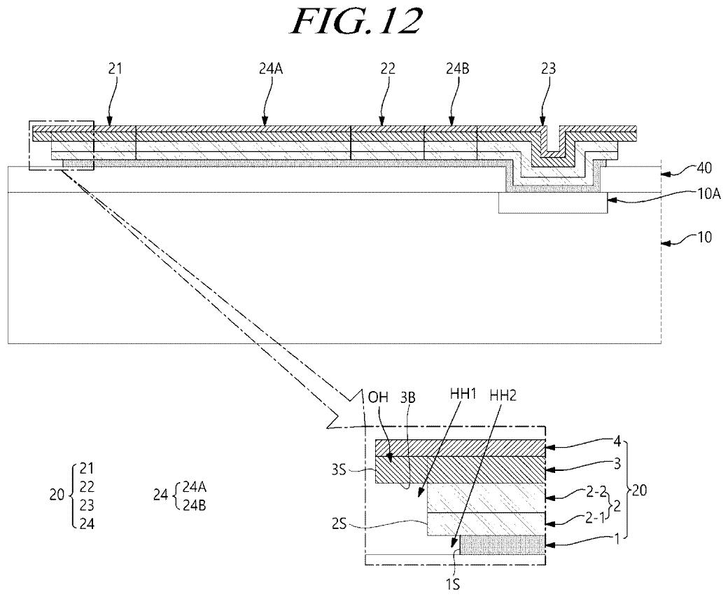

Referring to FIG. 12, through an etching process, a section of the pre-base metal layer 1′ (see FIG. 11) which does not overlap the electrically conductive layer 2 may be removed.

In the process of etching the pre-base metal layer 1′ (see FIG. 11) so that the pre-base metal layer 1′ (see FIG. 11) does not remain in a region not overlapping the electrically conductive layer 2, over-etching may be performed. As a result of the over-etching, a second horizontal groove HH2 may be formed under the outer peripheral section of the electrically conductive layer 2. Although not illustrated, the second horizontal groove HH2 may extend continuously along a side surface 1S of a base metal layer 1.

As the second horizontal groove HH2 is formed, the outer peripheral section of the electrically conductive layer 2 has an overhang structure which is not supported by the base metal layer 1. The side surface 2S of the electrically conductive layer 2 may be spaced apart from the side surface 1S of the base metal layer 1, and the edge section of a bottom surface 2B of the electrically conductive layer 2 may be exposed between the side surface 2S of the electrically conductive layer 2 and the side surface 1S of the base metal layer 1.

The base metal layer 1, the electrically conductive layer 2, the barrier metal layer 3 and the bonding metal layer 4 may configure a redistribution line 20. The redistribution line 20 may include a wire bonding pad section 21, a bump bonding pad section 22, an overlapping pad section 23, and trace sections 24: 24A and 24B.

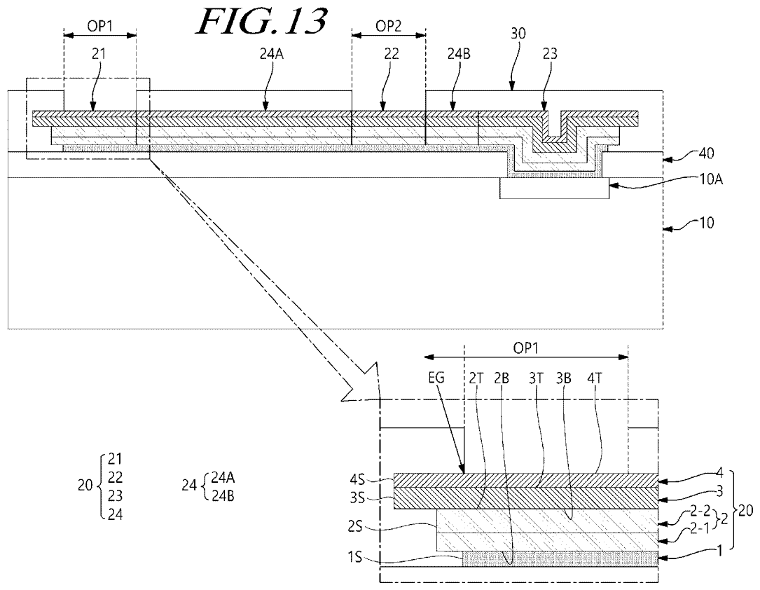

Referring to FIG. 13, a first dielectric layer 30 which covers the redistribution line 20 and the second dielectric layer 40 may be formed, and a first opening OP1 which exposes the wire bonding pad section 21 of the redistribution line 20 and a second opening OP2 which exposes the bump bonding pad section 22 of the redistribution line 20 may be formed in the first dielectric layer 30.

The first dielectric layer 30 may be formed to cover the overlapping pad section 23 and the trace sections 24: 24A and 24B of the redistribution line 20. The first dielectric layer 30 may extend to cover the side surface of the wire bonding pad section 21 and cover the edge section of the top surface of the wire bonding pad section 21. Specifically, the first dielectric layer 30 may be formed to cover, in the wire bonding pad section 21, a side surface 4S of the bonding metal layer 4, the side surface 3S of the barrier metal layer 3, the side surface 2S of the electrically conductive layer 2 and the side surface 1S of the base metal layer 1. The first dielectric layer 30 may extend to cover, in the wire bonding pad section 21, the edge section of the top surface 4T of the bonding metal layer 4. Accordingly, an edge EG of the first opening OP1 may be spaced apart from the side surface 4S of the bonding metal layer 4 of the wire bonding pad section 21. The first opening OP1 might not overlap the flange section OH of the barrier metal layer 3 which has the overhang structure.

The first dielectric layer 30 may be formed to fill the first horizontal groove HH1 (see FIG. 12) and cover the bottom surface 3B of the flange section OH of the barrier metal layer 3 of the wire bonding pad section 21 which protrudes beyond the side surface 2S of the electrically conductive layer 2 of the wire bonding pad section 21. The first dielectric layer 30 may fill the second horizontal groove HH2 (see FIG. 12). In the wire bonding pad section 21, the outer peripheral section of the bottom surface 2B of the electrically conductive layer 2 may protrude beyond the side surface 1S of the base metal layer 1. In the wire bonding pad section 21, the first dielectric layer 30 may be formed to cover the outer peripheral section of the bottom surface 2B of the electrically conductive layer 2.

The second opening OP2 of the first dielectric layer 30 may be formed to expose the top surface and the side surface of the bump bonding pad section 22 (see FIG. 7).

Specifically, in the bump bonding pad section 22 (see FIG. 7), the second opening OP2 may be formed to expose the top surface 4T (see FIG. 7) and the side surface 4S (see FIG. 7) of the bonding metal layer 4 (see FIG. 7), the side surface 3S (see FIG. 7) of the barrier metal layer 3 (see FIG. 7), the side surface 2S (see FIG. 7) of the electrically conductive layer 2 (see FIG. 7), the edge section of the bottom surface 3B (see FIG. 7) of the barrier metal layer 3 (see FIG. 7) and the side surface 1S (see FIG. 7) of the base metal layer 1 (see FIG. 7).

The first dielectric layer 30 may be made of a photosensitive polymer material such as polyimide, and after forming the first and second openings OP1 and OP2 in the first dielectric layer 30, a baking process for baking the photosensitive polymer material may be performed.

In a state in which the first dielectric layer 30 covers the side surface 3S of the barrier metal layer 3 of the wire bonding pad section 21 so that the side surface 3S of the barrier metal layer 3 of the wire bonding pad section 21 is not exposed to the outside, the baking process for baking the first dielectric layer 30 may be performed.

Accordingly, in an embodiment, it is possible to prevent or mitigate a layer serving as a metal diffusion path from being generated on the side surface 3S of the barrier metal layer 3 of the wire bonding pad section 21 during the baking process. In an embodiment, when the side surface 3S of the barrier metal layer 3 is exposed, process by-products may combine with the exposed side surface 3S to form a metal inorganic compound. In an embodiment, when the barrier metal layer 3 includes nickel, the metal inorganic compound may be nickel sulfide in which nickel combines with sulfur. In an embodiment, because the baking process is performed in the state in which the first dielectric layer 30 covers the side surface 3S of the barrier metal layer 3 of the wire bonding pad section 21, even when the baking process is performed at a temperature range in which a sulfur constituent remaining after being used in a semiconductor device manufacturing process may react with nickel, it is possible to suppress or prevent nickel sulfide from being generated on the side surface 3S of the barrier metal layer 3 of the wire bonding pad section 21. Therefore, in an embodiment, it is possible to suppress the metal of the electrically conductive layer 2 from diffusing to the bonding metal layer 4 of the wire bonding pad section 21 through nickel sulfide.

The semiconductor device 100 based on the embodiment of the disclosed technology may be used to manufacture a semiconductor package.

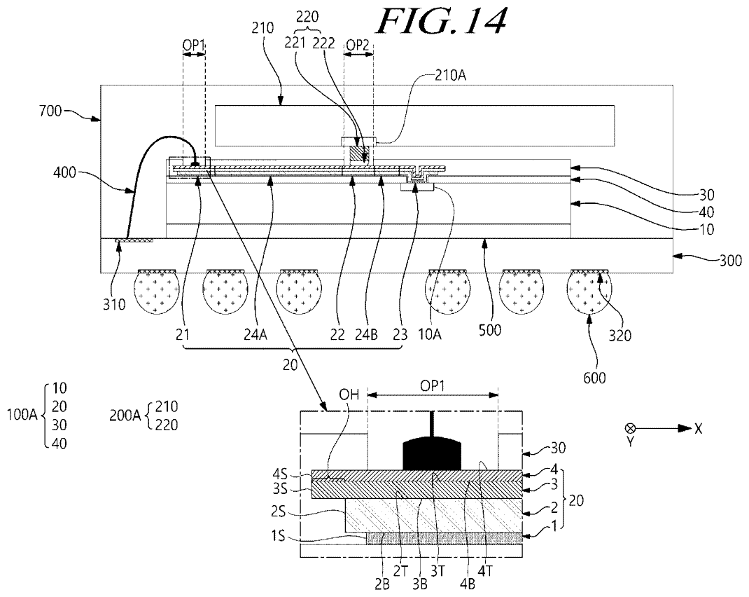

FIG. 14 is a cross-sectional view for explaining a semiconductor package based on an embodiment of the disclosed technology.

Referring to FIG. 14, the semiconductor package based on the embodiment of the disclosed technology may include a first semiconductor device 100A, a second semiconductor device 200A, a package substrate 300, and a metal wire 400. The semiconductor package based on the embodiment of the disclosed technology may further include an adhesive layer 500, a connection structure 600, and a molding member 700.

The package substrate 300 may include a circuit and/or interconnection structure for electrically connecting the first semiconductor device 100A and the second semiconductor device 200A to an external device. For example, the package substrate 300 may include a printed circuit board (PCB), an interposer, a redistribution layer, or the like. A top surface substrate pad 310 may be disposed on the top surface of the package substrate 300. Top surface substrate pads 310 may include bond fingers. Bottom surface substrate pads 320 for connection to connection structures 600 may be disposed on the bottom surface of the package substrate 300. The connection structures 600 may be electrically connected to another semiconductor package or printed circuit board. The connection structures 600 may include solder balls. When the connection structure 600 is a solder ball, the bottom surface substrate pad 320 may include a ball land. Although not illustrated, the top surface substrate pad 310 may be electrically connected to a corresponding bottom surface substrate pad 320 through the circuit and/or interconnection structure in the package substrate 300.

The first semiconductor device 100A may be the semiconductor device 100 described above with reference to FIGS. 1 to 13. The first semiconductor device 100A may include a first semiconductor chip 10, redistribution lines 20, and a first dielectric layer 30. The first semiconductor device 100A may further include a second dielectric layer 40 which covers the first semiconductor chip 10 under the redistribution lines 20 and has an opening that exposes a chip pad 10A of the first semiconductor chip 10.

The first semiconductor chip 10 may be disposed on the package substrate 300 in a face-up type so that an active surface on which the chip pad 10A is disposed faces up, and the inactive surface of the first semiconductor chip 10 may be attached onto the package substrate 300 by the adhesive layer 500.

The redistribution line 20 is disposed on the second dielectric layer 40 and the chip pad 10A of the first semiconductor chip 10, and extends to the edge of the first semiconductor chip 10 while being connected to the chip pad 10A of the first semiconductor chip 10. Although only one chip pad 10A and only one redistribution line 20 are illustrated in the cross-section shown in FIG. 14, a plurality of chip pads 10A are disposed in at least one column in the Y-axis direction of an X-Y plane, and a plurality of redistribution lines 20 are connected to the plurality of chip pads 10A, respectively.

The redistribution line 20 may include a wire bonding pad section 21 which is disposed adjacent to the edge of the first semiconductor chip 10, a bump bonding pad section 22 which is connected to the bump of a second semiconductor chip 210, an overlapping pad section 23 which is connected to the chip pads 10A of the first semiconductor chip 10, and trace sections 24: 24A and 24B which connect them to each other.

The bump bonding pad section 22 of the redistribution line may be disposed by being offset in the X-axis direction with respect to the chip pad 10A of the first semiconductor chip 10.

The redistribution line 20 may include an electrically conductive layer 2, a barrier metal layer 3 on the electrically conductive layer 2, and a bonding metal layer 4 on the barrier metal layer 3. Besides, the redistribution line 20 may further include a base metal layer 1 under the electrically conductive layer 2.

The base metal layer 1 may be disposed on the surface of the second dielectric layer 40 and the surface of the chip pad 10A. The base metal layer 1 may contact the chip pad 10A of the first semiconductor chip 10, and may electrically connect the chip pad 10A and the electrically conductive layer 2.

The electrically conductive layer 2 may be disposed on the base metal layer 1. The outer peripheral section of the electrically conductive layer 2 has an overhang structure which is not supported by the underlying base metal layer 1. The outer peripheral section of the electrically conductive layer 2 has the overhang structure which is continuous along a side surface 1S of the base metal layer 1.

The barrier metal layer 3 is disposed on a top surface 2T of the electrically conductive layer 2. The barrier metal layer 3 has a flange section OH which protrudes beyond a side surface 2S of the electrically conductive layer 2. The flange section OH of the barrier metal layer 3 has an overhang structure which is not supported by the underlying electrically conductive layer 2. The flange section OH of the barrier metal layer 3 has the overhang structure which is continuous along the side surface 2S of the electrically conductive layer 2. A side surface 3S of the barrier metal layer 3 may protrude beyond the side surface 2S of the electrically conductive layer 2.

The bonding metal layer 4 is disposed on a top surface 3T of the barrier metal layer 3.

The first dielectric layer 30 is disposed on the first semiconductor chip 10 and the redistribution line 20, and has a first opening OP1 which exposes the wire bonding pad section 21 of the redistribution line 20 and a second opening OP2 which exposes the bump bonding pad section 22 of the redistribution line 20. The first dielectric layer 30 may extend to cover the side surface of the wire bonding pad section 21 and cover the edge section of the top surface the wire bonding pad section 21.

The first dielectric layer 30 is provided to cover the side surface of the wire bonding pad section 21. Specifically, the first dielectric layer 30 is provided to cover, in the wire bonding pad section 21, a side surface 4S of the bonding metal layer 4, the side surface 3S of the barrier metal layer 3, the side surface 2S of the electrically conductive layer 2 and the side surface 1S of the base metal layer 1. In addition, the first dielectric layer 30 is provided to cover, in the wire bonding pad section 21, the edge section of a bottom surface 3B of the barrier metal layer 3 between the side surface 2S of the electrically conductive layer 2 and the side surface 3S of the barrier metal layer 3.

In an embodiment, in the wire bonding pad section 21, the first dielectric layer 30 may cover the side surface 3S of the barrier metal layer 3 to prevent or mitigate a layer acting as a metal diffusion path from being generated. In an embodiment, because the first dielectric layer 30 suppresses the generation of the metal diffusion path, it is possible to suppress or prevent the occurrence of a defect in which the surface of the bonding metal layer 4 is discolored or the metal wire 400 comes off without being bonded to the bonding metal layer 4.

The first dielectric layer 30 may extend to cover, in the wire bonding pad section 21, the edge section of a top surface 4T of the bonding metal layer 4. Accordingly, an edge EG of the first opening OP1 may be spaced apart from the side surface 4S of the bonding metal layer 4. The edge EG of the first opening OP1 may be disposed on the top surface 4T of the bonding metal layer 4, and the first dielectric layer may continuously cover the edge section of the top surface 4T of the bonding metal layer 4 along the edge EG of the first opening OP1.

The metal wire 400 may be bonded to the exposed section of the top surface 4T of the bonding metal layer 4 of the wire bonding pad section 21 which is exposed by the first opening OP1 of the first dielectric layer 30. The exposed section of the top surface 4T of the bonding metal layer 4 of the wire bonding pad section 21 which is exposed by the first opening OP1 may be defined as a wire bonding area. The wire bonding area might not overlap the flange section OH of the barrier metal layer 3 which has the overhang structure.

The second semiconductor device 200A includes the second semiconductor chip 210 and conductive bumps 220 which are connected to chip pads 210A of the second semiconductor chip 210. The second semiconductor chip 210 is connected to the bump bonding pad section 22 of the redistribution line 20 of the first semiconductor device 100A through the conductive bump 220. Although only one chip pad 210A and only one conductive bump 220 are illustrated in the cross-section shown in FIG. 14, a plurality of chip pads 210A may be disposed in at least one column in the Y-axis direction of the X-Y plane, and a plurality of conductive bumps 220 may be connected to the plurality of chip pads 210A, respectively.

The second semiconductor chip 210 may be substantially the same semiconductor chip as the first semiconductor chip 10. In this case, the chip pads 210A of the second semiconductor chip 210 may have the same arrangement structure as the chip pads 10A of the first semiconductor chip 10.

Apart from the first semiconductor chip 10 which is disposed so that the active surface on which the chip pads 10A are disposed faces up, the second semiconductor chip 210 may be disposed over the first semiconductor device 100A in a face-down type so that an active surface on which the chip pads 210A are disposed faces down.

The conductive bumps 220 may be positioned to overlap the chip pads 210A. The conductive bump 220 may include a conductive pillar 221 and a solder layer 222. The conductive pillar 221 may be disposed under the second semiconductor chip 210. The solder layer 222 may be disposed at the lower end of the conductive pillar 221, and may be bonded to the bump bonding pad section 22 of the redistribution line 20.

The second semiconductor chip 210 may be connected to the first semiconductor device 100A while being offset in the X-axis direction with respect to the first semiconductor chip 10. In an embodiment, because the bump bonding pad sections 22 of the redistribution lines 20 of the first semiconductor device 100A are disposed by being offset in the X-axis direction with respect to the chip pads 10A of the first semiconductor chip 10, the arrangement of the chip pads 210A of the second semiconductor chip 210 is the same as the arrangement of the chip pads 10A of the first semiconductor chip and the conductive bumps 220 overlap the chip pads 210A of the second semiconductor chip 210, the second semiconductor chip 210 may be connected to the first semiconductor device 100A in a state in which it is offset in the X-axis direction with respect to the first semiconductor chip 10. Accordingly, the first semiconductor chip 10 and the second semiconductor chip 210 may partially overlap each other.

The molding member 700 is formed to surround the first and second semiconductor devices 100A and 200A and the metal wires 400. The molding member 700 may seal the first and second semiconductor devices 100A and 200A and the metal wires 400 to protect the first and second semiconductor devices 100A and 200A and the metal wires 400 from an external environment. The first semiconductor device 100A and the second semiconductor device 200B may be spaced apart from each other, and the molding member 700 may extend between the first semiconductor device 100A and the second semiconductor device 200B. In FIG. 14, the molding member 700 is formed to substantially completely cover the second semiconductor device 200A. However, the embodiment of the disclosed technology is not limited thereto, and the molding member 700 may be formed to expose a section of the surface of the second semiconductor device 200A.

In an embodiment, the molding member 700 may include an encapsulant material such as an epoxy molding compound (EMC) material. In an embodiment, the encapsulant material may include, for example, an epoxy resin constituent and fillers dispersed therein.

Although examples of embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A semiconductor device comprising:
a semiconductor chip comprising a chip pad;
a redistribution line disposed on the semiconductor chip, wherein the redistribution line is connected to the chip pad, and the redistribution line comprises a wire bonding pad section; and
a first dielectric layer disposed on the semiconductor chip and the redistribution line, the first dielectric layer comprises a first opening that exposes the wire bonding pad section,
wherein the redistribution line comprises a copper layer, a nickel layer on the copper layer, and a gold layer on the nickel layer, the nickel layer comprises a side surface protruding beyond a side surface of the copper layer.

2. The semiconductor device according to claim 1,
wherein the first dielectric layer covers a side surface of the gold layer, the side surface of the nickel layer, and the side surface of the copper layer.

3. The semiconductor device according to claim 2,
wherein the first dielectric layer is further extended to cover a bottom surface of the nickel layer.

4. The semiconductor device according to claim 1,
wherein the first dielectric layer is extended on a top surface of the gold layer to expose the wire bonding pad section.

5. The semiconductor device according to claim 4, wherein the first opening is spaced apart from the side surface of the gold layer.

6. The semiconductor device according to claim 1, further comprising:
a second dielectric layer disposed on the semiconductor chip, the second dielectric layer comprises an opening which exposes the chip pad.

7. The semiconductor device according to claim 6,
wherein the redistribution line further comprises a titanium layer disposed between the copper layer and the second dielectric layer, and
wherein the titanium layer is extended to be disposed between the copper layer and the chip pad.

8. The semiconductor device according to claim 7, wherein the side surface of the copper layer protrudes beyond a side surface of the titanium layer.

9. The semiconductor device according to claim 1,
wherein the redistribution line further has a bump bonding pad section, and
wherein the first dielectric layer further has a second opening which exposes a top surface and a side surface of the bump bonding pad section.

10. The semiconductor device according to claim 1, wherein
a flange section of the nickel layer in the wire bonding pad section comprises an overhang structure which protrudes beyond the side surface of the copper layer, and
the flange section of the nickel layer overlaps with the first dielectric layer.

11. A semiconductor device comprising:
a semiconductor chip;
a redistribution line disposed on the semiconductor chip, the redistribution line comprises a wire bonding pad section; and
a first dielectric layer disposed on the semiconductor chip and the redistribution line, the first dielectric layer comprises a first opening that exposes the wire bonding pad section,
wherein the redistribution line comprises an electrically conductive layer, a barrier metal layer disposed on the electrically conductive layer, and a bonding metal layer on the barrier metal layer, the barrier metal layer comprises a flange section protruding beyond a side surface of the electrically conductive layer.

12. The semiconductor device according to claim 11,
wherein the first dielectric layer is configured to cover a side surface of the bonding metal layer, a side surface of the barrier metal layer, the side surface of the electrically conductive layer.

13. The semiconductor device according to claim 12,
wherein the first dielectric layer is further extended to cover a bottom surface of the barrier metal layer.

14. The semiconductor device according to claim 11,
wherein the first dielectric layer extends on a top surface of the bonding metal layer to expose the wire bonding pad section.

15. The semiconductor device according to claim 14, wherein the first opening is spaced apart from the side surface of the bonding metal layer.

16. The semiconductor device according to claim 11,
wherein the redistribution line further has a bump bonding pad section,
wherein the first dielectric layer further has a second opening which exposes the bump bonding pad section.

17. The semiconductor device according to claim 11, wherein the redistribution line further comprises a base metal layer which is disposed under the electrically conductive layer.

18. The semiconductor device according to claim 17, wherein the side surface of the electrically conductive layer protrudes beyond a side surface of the base metal layer.

19. The semiconductor device according to claim 11, wherein the flange section of the barrier metal layer overlaps with the first dielectric layer.

20. A semiconductor package comprising:
a first semiconductor device including a first semiconductor chip, a redistribution line disposed on the first semiconductor chip, and a first dielectric layer disposed on the first semiconductor chip and the redistribution line, the redistribution line comprises a wire bonding pad section and a bump bonding pad section, and the first dielectric layer comprises a first opening that exposes the wire bonding pad section and a second opening that exposes the bump bonding pad section; and
a second semiconductor device including a second semiconductor chip and a conductive bump that is connected to the second semiconductor chip, the second semiconductor device is stacked on the first semiconductor device so that the conductive bump is bonded to the bump bonding pad section of the redistribution line,
wherein the redistribution line comprises an electrically conductive layer, a barrier metal layer disposed on the electrically conductive layer, and a bonding metal layer on the barrier metal layer, the barrier metal layer comprises a side surface protruding beyond a side surface of the electrically conductive layer.

21. The semiconductor package according to claim 20, wherein the first dielectric layer is provided to cover a side surface of the bonding metal layer, the side surface of the barrier metal layer, the side surface of the electrically conductive layer.

22. The semiconductor package according to claim 21,
wherein the first dielectric layer is further extended to cover a bottom surface of the barrier metal layer.

23. The semiconductor package according to claim 20, wherein the first opening is spaced apart from a side surface of the bonding metal layer.

24. The semiconductor package according to claim 20,
wherein the redistribution line further comprises a base metal layer which is disposed between the electrically conductive layer and the semiconductor chip, and
wherein the side surface of the electrically conductive layer protrudes beyond a side surface of the base metal layer.

25. The semiconductor package according to claim 20, wherein the barrier metal layer comprises nickel.

26. The semiconductor package according to claim 20, wherein the electrically conductive layer comprises copper, and the bonding metal layer comprises gold.

27. The semiconductor package according to claim 20,
wherein the first semiconductor chip comprises a chip pad which is connected to the redistribution line, and
wherein the bump bonding pad section is offset in a first direction with respect to the chip pad.

28. The semiconductor package according to claim 27, wherein the second semiconductor device is offset in the first direction with respect to the first semiconductor device.

29. The semiconductor package according to claim 20, further comprising:
a package substrate comprising a top surface substrate pad, and supporting the first and second semiconductor devices;
a metal wire comprising one end which is connected to the top surface substrate pad and the other end which is connected to the wire bonding pad section; and
a molding member sealing the first and second semiconductor devices and the metal wire.

30. The semiconductor package according to claim 20,
wherein in the wire bonding pad section, a flange section of the barrier metal layer comprises an overhang structure protruding beyond the side surface of the electrically conductive layer, and
wherein the overhang structure overlaps with the first dielectric layer.
